(19) United States
(12) Patent Application Publication
(10) Pub. No.: US 2024/0284606 A1
(43) Pub. Date: Aug. 22, 2024

(54) WIRING SUBSTRATE

(71) Applicant: IBIDEN CO., LTD., Ogaki (JP)

(72) Inventors: Toshiki FURUTANI, Ogaki (JP); Masashi KUWABARA, Ibi-gun (JP); Susumu KAGOHASHI, Ogaki (JP)

(73) Assignee: IBIDEN CO., LTD., Ogaki (JP)

(21) Appl. No.: 18/581,432

(22) Filed: Feb. 20, 2024

(30) Foreign Application Priority Data
Feb. 21, 2023 (JP) 2023-025031

(51) Int. Cl. H05K 3/46; H05K 1/03; H05K 3/00; H05K 3/18; H05K 3/42

(52) U.S. Cl. CPC H05K 3/4688; H05K 1/0306; H05K 3/0011; H05K 3/188; H05K 3/423; H05K 3/4605; H05K 2201/0209; H05K 2201/0212

(57) ABSTRACT

A wiring substrate includes a core substrate including a glass substrate, a resin insulating layer including inorganic particles and resin, a conductor layer including a seed layer and an electrolytic plating layer such that the conductor layer includes signal wirings, and a via conductor formed in an opening formed in the resin insulating layer and including the seed layer and electrolytic plating layer extending from the conductor layer. The core substrate includes a through-hole conductor formed such that the core substrate has a through hole penetrating through the glass substrate and the through-hole conductor is formed in the through hole, the via conductor is electrically connected to the through-hole conductor formed in the core substrate, and the resin insulating layer is formed such that the surface upon which the conductor layer is formed includes the resin and an inner wall surface in the opening includes the resin and inorganic particles.

### CROSS-REFERENCE TO RELATED APPLICATIONS

The present application is based upon and claims the benefit of priority to Japanese Patent Application No. 2023-025031, filed Feb. 21, 2023, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2015-133473 describes a multilayer substrate having a core formed of a glass material. The entire contents of this publication are incorporated herein by reference.

### SUMMARY OF THE INVENTION

According to one aspect of the present invention, a wiring substrate includes a core substrate including a glass substrate, a resin insulating layer formed on the core substrate and including inorganic particles and resin, a conductor layer formed on a surface of the resin insulating layer and including a seed layer formed by sputtering and an electrolytic plating layer formed on the seed layer such that the conductor layer includes signal wirings, and a via conductor formed in the resin insulating layer such that the via conductor is formed in an opening formed in the resin insulating layer and includes the seed layer and electrolytic plating layer extending from the conductor layer. The core substrate includes a through-hole conductor formed such that the core substrate has a through hole penetrating through the glass substrate and that the through-hole conductor is formed in the through hole, the via conductor is formed such that the via conductor is electrically connected to the through-hole conductor formed in the core substrate, and the resin insulating layer is formed such that the surface upon which the conductor layer is formed includes the resin and that an inner wall surface in the opening includes the resin and the inorganic particles.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2A is a cross-sectional view schematically illustrating a method for manufacturing a wiring substrate according to an embodiment of the present invention;

FIG. 2B is a cross-sectional view schematically illustrating a method for manufacturing a wiring substrate according to an embodiment of the present invention;

FIG. 2C is a cross-sectional view schematically illustrating a method for manufacturing a wiring substrate according to an embodiment of the present invention;

FIG. 2D is a cross-sectional view schematically illustrating a method for manufacturing a wiring substrate according to an embodiment of the present invention;

FIG. 2E is a cross-sectional view schematically illustrating a method for manufacturing a wiring substrate according to an embodiment of the present invention;

FIG. 2F is a cross-sectional view schematically illustrating a method for manufacturing a wiring substrate according to an embodiment of the present invention;

FIG. 2G is a cross-sectional view schematically illustrating a method for manufacturing a wiring substrate according to an embodiment of the present invention;

FIG. 2H is a cross-sectional view schematically illustrating a method for manufacturing a wiring substrate according to an embodiment of the present invention;

FIG. 2I is a cross-sectional view schematically illustrating a method for manufacturing a wiring substrate according to an embodiment of the present invention;

FIG. 2J is a cross-sectional view schematically illustrating a method for manufacturing a wiring substrate according to an embodiment of the present invention;

FIG. 3 is a cross-sectional view schematically illustrating a method for manufacturing a wiring substrate of a modified example according to an embodiment of the present invention; and

FIG. 4 is a cross-sectional view schematically illustrating a method for manufacturing a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

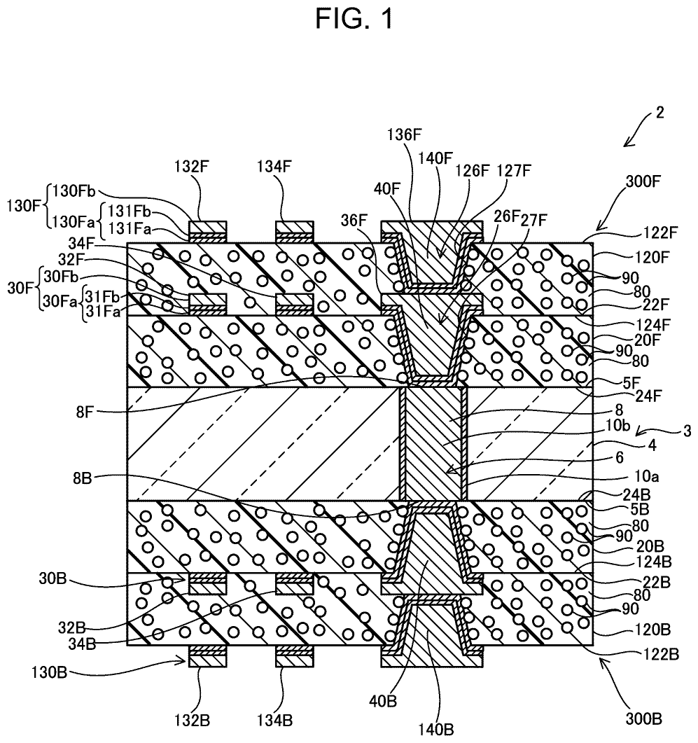

FIG. 1 is a cross-sectional view illustrating a wiring substrate 2 of an embodiment. As illustrated in FIG. 1, the wiring substrate 2 includes a core substrate 3, a front side build-up layer (300F), and a back side build-up layer (300B).

The core substrate 3 includes a substrate 4, through holes 6, and through-hole conductors 8. The substrate 4 has a front surface (5F) and a back surface (5B) on the opposite side with respect to the front surface (5F). The substrate 4 is formed of glass. The through holes 6 penetrate the substrate 4. The through holes 6 each have a substantially cylindrical shape. The through holes 6 each have a substantially constant diameter. It is also possible that the through holes 6 each have a substantially truncated cone shape. It is also possible that the through holes 6 each have a shape obtained by connecting two substantially conical shapes. The two cones are a front surface side cone and a back surface side cone. A bottom surface of the front surface side cone is positioned on the front surface (5F), and a bottom surface of the back surface side cone is positioned on the back surface (5B). In this case, a side surface of each of the through holes 6 is formed of a surface tapering from the front surface (5F) toward the back surface (5B) and a surface tapering from the back surface (5B) toward the front surface (5F).

The through-hole conductors 8 are respectively formed in the through holes 6. The through-hole conductors 8 are mainly formed of copper. The through-hole conductors 8 include a seed layer (10a) formed on inner wall surfaces of the through holes 6 and an electrolytic plating layer (10b) formed on the seed layer (10a). The electrolytic plating layer (10b) fills the through holes 6. The seed layer (10a) is formed by electroless plating. The through-hole conductors 8 each have an upper end (8F) and a lower end (8B). A surface of the upper end (8F) and the front surface (5F) form substantially the same flat surface. A surface of the lower end (8B) and the back surface (5B) form substantially the same flat surface. The upper end (8F) is exposed from the front surface (5F). The lower end (8B) is exposed from the back surface (5B).

The front side build-up layer (300F) is formed on the front surface (5F) of the substrate 4. The front side build-up layer (300F) includes front side resin insulating layers, front side conductor layers, and front side via conductors that penetrate the front side resin insulating layers. The front side conductor layers and the front side via conductors are electrically connected to the through-hole conductors 8. The front side resin insulating layers and the front side conductor layers are alternately laminated. The front side resin insulating layers in FIG. 1 are a first resin insulating layer (20F) and a second resin insulating layer (120F). The front side conductor layers are a first conductor layer (30F) and a second conductor layer (130F). The front side via conductors are first via conductors (40F) and second via conductors (140F).

The first resin insulating layer (20F) has a first surface (22F) and a second surface (24F) on the opposite side with respect to the first surface (22F). The first resin insulating layer (20F) is formed on the front surface (5F) of the substrate 4 with the second surface (24F) facing the front surface (5F). In the example in FIG. 1, the second surface (24F) is in contact with the front surface (5F). The second surface (24F) is in contact with a part of the upper end (8F). No conductor circuit exists between the front surface (5F) and the second surface (24F). No conductor circuit is formed on the front surface (5F). The first resin insulating layer (20F) has first openings (26F) that respectively reach the upper ends (8F) of the through-hole conductors 8. The first openings (26F) each have an opening (top opening) on the first surface (22F) and an opening (bottom opening) on the second surface (24F). The top opening and the bottom opening each have a substantially circular shape. The bottom opening can expose the upper end (8F) and the front surface (5F) at the same time. In this case, the front surface (5F) around the upper end (8F) is exposed. It is also possible that the bottom opening exposes a part of the upper end (8F) and the front surface (5F) around the part (first example). It is also possible that the bottom opening exposes the entire upper end (8F) and the front surface (5F) around the upper end (8F) (second example). As illustrated in FIG. 1, the bottom opening can expose only the upper end (8F) (third example). Two examples among the first example, the second example and the third example may be mixed. All of the first example, the second example and the third example may be mixed. It is preferable that the first example and the third example are mixed. In this case, the upper ends (8F) of some of the through-hole conductors 8 are exposed by the openings of the first example, and the upper ends (8F) of the remaining through-hole conductors are exposed by the openings of the third example. The first resin insulating layer (20F) is formed of a resin 80 and a large number of inorganic particles 90 dispersed in the resin 80. The resin 80 is an epoxy resin. Examples of the resin include a thermosetting resin and a photocurable resin. The inorganic particles 90 are glass particles. It is also possible that the inorganic particles 90 are alumina particles. A content of the inorganic particles 90 in the first resin insulating layer (20F) is 75 wt % or more.

The first surface (22F) of the first resin insulating layer (20F) is formed only of the resin 80. No inorganic particles 90 are exposed from the first surface (22F). The first surface (22F) does not include surfaces of the inorganic particles 90. No unevenness is formed on the first surface (22F) of the first resin insulating layer (20F). The first surface (22F) is not roughened. The first surface (22F) is formed smooth. On the other hand, the inorganic particles 90 are exposed on an inner wall surface (27F) of each of the first openings (26F). The inner wall surface (27F) of each of the first openings (26F) includes surfaces of the inorganic particles 90. The inner wall surface (27F) of each of the first openings (26F) has unevenness. The inner wall surface (27F) of each of the first openings (26F) is formed of an exposed surface of the resin 80 and exposed surfaces of the inorganic particles 90.

The first conductor layer (30F) is formed on the first surface (22F) of the first resin insulating layer (20F). The first conductor layer (30F) includes a first signal wiring (32F), a second signal wiring (34F), and lands (36F). Although not illustrated in the drawings, the first conductor layer (30F) also includes conductor circuits other than the first signal wiring (32F), the second signal wiring (34F), and the lands (36F). The first signal wiring (32F) and the second signal wiring (34F) form a pair wiring. The first conductor layer (30F) is mainly formed of copper. The first conductor layer (30F) is formed of a seed layer (30Fa) and an electrolytic plating layer (30Fb) on the seed layer (30Fa). The seed layer (30Fa) is formed by sputtering. The seed layer (30Fa) is formed of a first layer (31Fa) on the first surface (22F) and a second layer (31Fb) on the first layer (31Fa). The first layer (31Fa) is in contact with the first surface (22F). The second layer (31Fb) is not essential. The first layer (31Fa) is formed of a copper alloy. A copper content in the copper alloy is 90 wt % or more. The second layer (31Fb) is formed of copper. The electrolytic plating layer (30Fb) is formed of copper.

The first resin insulating layer (20F) is formed on the glass substrate 4. Since glass is excellent in flatness, the first surface (22F) of the first resin insulating layer (20F) is also excellent in flatness. When no conductive circuit is formed between the front surface (5F) and the first resin insulating layer (20F), the first surface (22F) can follow the front surface (5F). The first surface (22F) can have similar flatness as the front surface (5F). In the embodiment, fine wirings can be formed on the first surface (22F). For example, the first conductor layer (30F) can have wirings having widths of 1.5 μm or more and 3.5 μm or less. A width of a space between adjacent wirings is 1.5 μm or more and 3.5 μm or less.

The first via conductors (40F) are respectively formed in the first openings (26F). The first via conductors (40F) electrically connect the through-hole conductors 8 to the first conductor layer (30F). The first via conductors (40F) electrically connect the through-hole conductors 8 to the lands (36F) of the first via conductor (40F). The first via conductors (40F) are formed of a seed layer (30Fa) and an electrolytic plating layer (30Fb) on the seed layer (30Fa). The seed layer (30Fa) forming the first via conductors (40F) and the seed layer (30Fa) forming the first conductor layer (30F) are common. The electrolytic plating layer (30Fb) forming the first via conductors (40F) and the electrolytic plating layer (30Fb) forming the first conductor layer (30F) are common. The seed layer (30Fa) forming the first via conductors (40F) is formed of a first layer (31Fa), which is formed on the inner wall surfaces (27F) of the first openings (26F) and on the upper ends (8F) of the through-hole conductors 8 exposed from the first openings (26F), and a second layer (31Fb) on the first layer (31Fa). In FIG. 1, the first via conductors (40F) are connected to the upper ends (8F). The first layer (31Fa) is in contact with the upper ends (8F) of the through-hole conductors 8 and the inner wall surfaces (27F). The first via conductors (40F) are respectively directly formed on the upper ends (8F).

The second resin insulating layer (120F) is formed on the first surface (22F) of the first resin insulating layer (20F) and on the first conductor layer (30F). The first conductor layer (30F) is formed between the second resin insulating layer (120F) and the first resin insulating layer (20F). The second resin insulating layer (120F) has a first surface (122F) and a second surface (124F) on the opposite side with respect to the first surface (122F). The second surface (124F) of the second resin insulating layer (120F) faces the first conductor layer (30F). Similar to the first resin insulating layer (20F), the second resin insulating layer (120F) is formed of a resin 80 and inorganic particles 90. Therefore, the material of the second resin insulating layer (120F) is similar to the material of the first resin insulating layer (20F). The first surface (122F) of the second resin insulating layer (120F) is similar to the first surface (22F) of the first resin insulating layer (20F).

The second resin insulating layer (120F) has second openings (126F) that expose the first conductor layer (30F). The second openings (126F) respectively expose the lands (36F). The second openings (126F) each have an inner wall surface (127F). The first openings (26F) and the second openings (126F) are similar. Therefore, the inner wall surfaces (27F) of the first openings (26F) and the inner wall surfaces (127F) of the second openings (126F) are similar.

The second conductor layer (130F) is formed on the first surface (122F) of the second resin insulating layer (120F). The second conductor layer (130F) includes a first signal wiring (132F), a second signal wiring (134F), and lands (136F). Although not illustrated in the drawings, the second conductor layer (130F) also includes conductor circuits other than the first signal wiring (132F), the second signal wiring (134F), and the lands (136F). The first signal wiring (132F) and the second signal wiring (134F) form a pair wiring. The second conductor layer (130F) and the first conductor layer (30F) are similar. Therefore, the second conductor layer (130F) is formed of a seed layer (130Fa) and an electrolytic plating layer (130Fb) on the seed layer (130Fa). The seed layer (130Fa) is formed of a first layer (131Fa) and a second layer (131Fb) on the first layer (131Fa).

The second via conductors (140F) are respectively formed in the second openings (126F). The second via conductors (140F) electrically connect the first conductor layer (30F) and the second conductor layer (130F). In FIG. 1, the second via conductors (140F) electrically connect the lands (36F) and the lands (136F). The second via conductors (140F) and the first via conductors (40F) are similar. Therefore, the second via conductors (140F) are formed of a seed layer (130Fa) and an electrolytic plating layer (130Fb) on the seed layer (130Fa). The seed layer (130Fa) is formed of a first layer (131Fa) and a second layer (131Fb) on the first layer (131Fa).

The back side build-up layer (300B) includes back side resin insulating layers, back side conductor layers, and back side via conductors that penetrate the back side resin insulating layers. The back side resin insulating layers and the back side conductor layers are alternately laminated. The back side conductor layers and the back side via conductors are electrically connected to the through-hole conductors 8. The back side resin insulating layers in FIG. 1 are a first resin insulating layer (20B) having a first surface (22B) and a second surface (24B) and a second resin insulating layer (120B) having a first surface (122B) and a second surface (124B). The back side conductor layers are a first conductor layer (30B) and a second conductor layer (130B). The first conductor layer (30B) and the second conductor layer (130B) include first signal wirings (32B, 132B) and second signal wirings (34B, 134B). The back side via conductors are first via conductors (40B) and second via conductors (140B).

The front side build-up layer (300F) and the back side build-up layer (300B) are similar. Therefore, the front side resin insulating layers forming the front side build-up layer (300F) and the back side resin insulating layers forming the back side build-up layer (300B) are similar. The back side resin insulating layers are each formed of a resin 80 and inorganic particles 90. The first surface of each of the resin insulating layers is formed only of the resin. The front side conductor layers and the back side conductor layers are similar. The openings for the front side via conductors and the openings for the back side via conductors are similar. The inner wall surface of each of the openings for the via conductors is formed of an exposed surface of the resin and exposed surfaces of the inorganic particles. The front side via conductors and the back side via conductors are similar.

Although not illustrated in the drawings, each side of the wiring substrate 2 has a length of 50 mm or more. The length of each side is preferably 100 mm or more. The length of each side is 250 mm or less. A length of a signal wiring formed according to the embodiment is 5 mm or more. The length of the signal wiring may be 10 mm or more and 20 mm or less.

### Method for Manufacturing Wiring Substrate

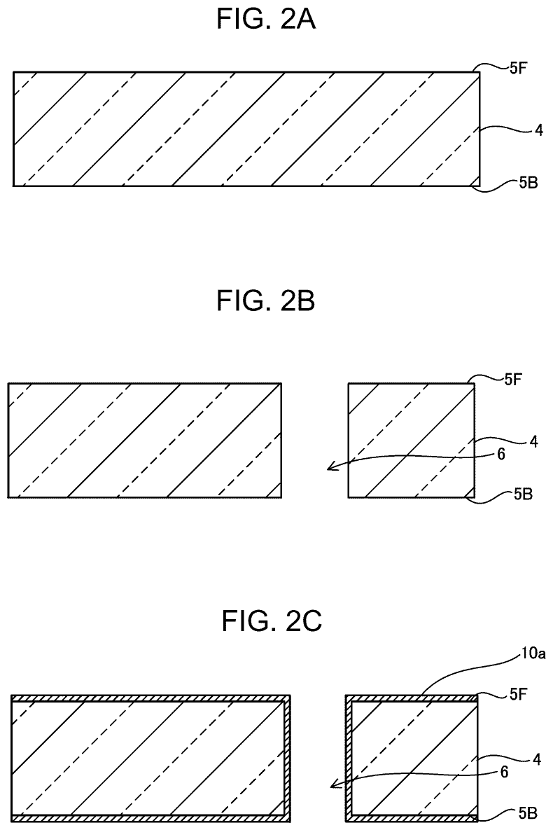

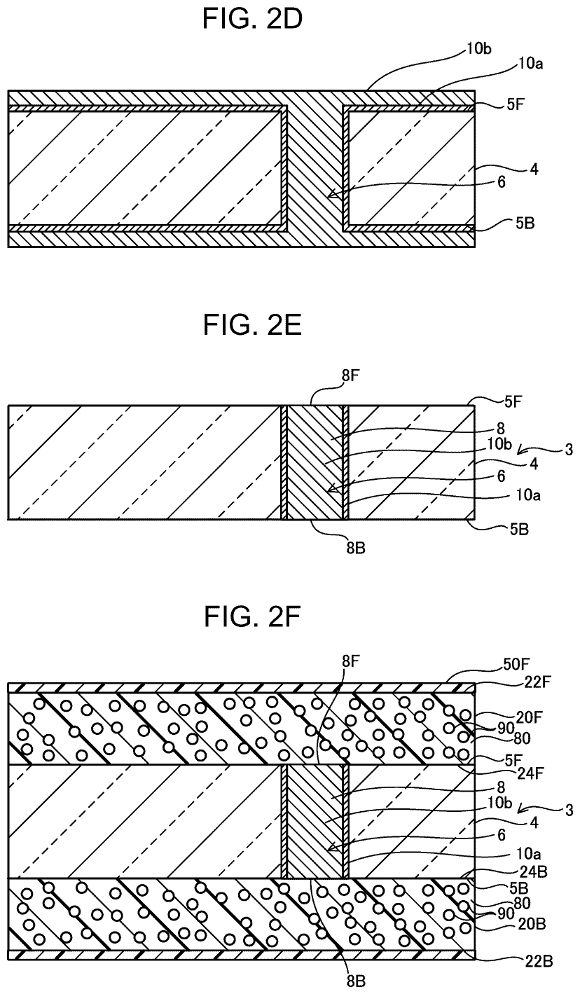

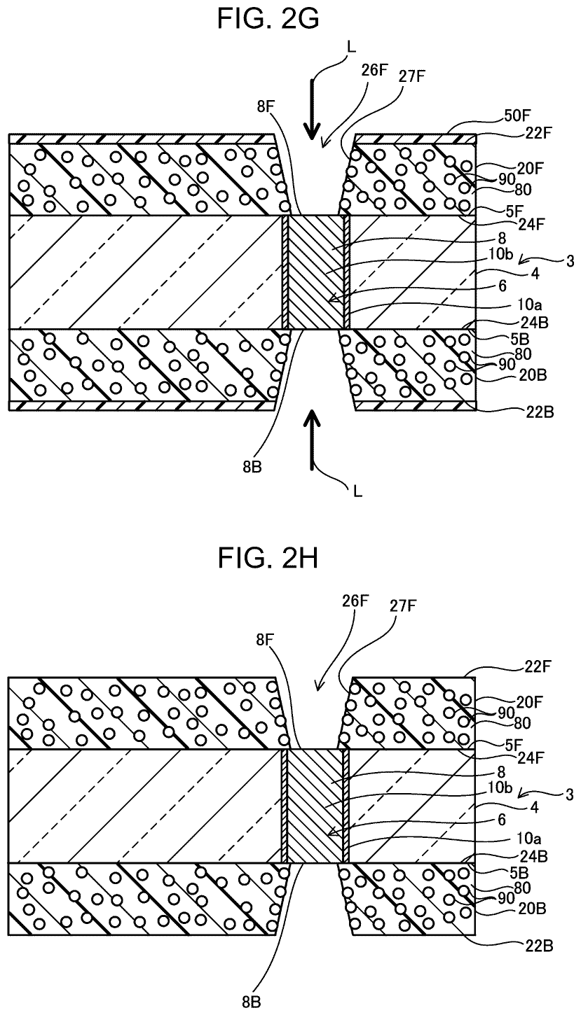

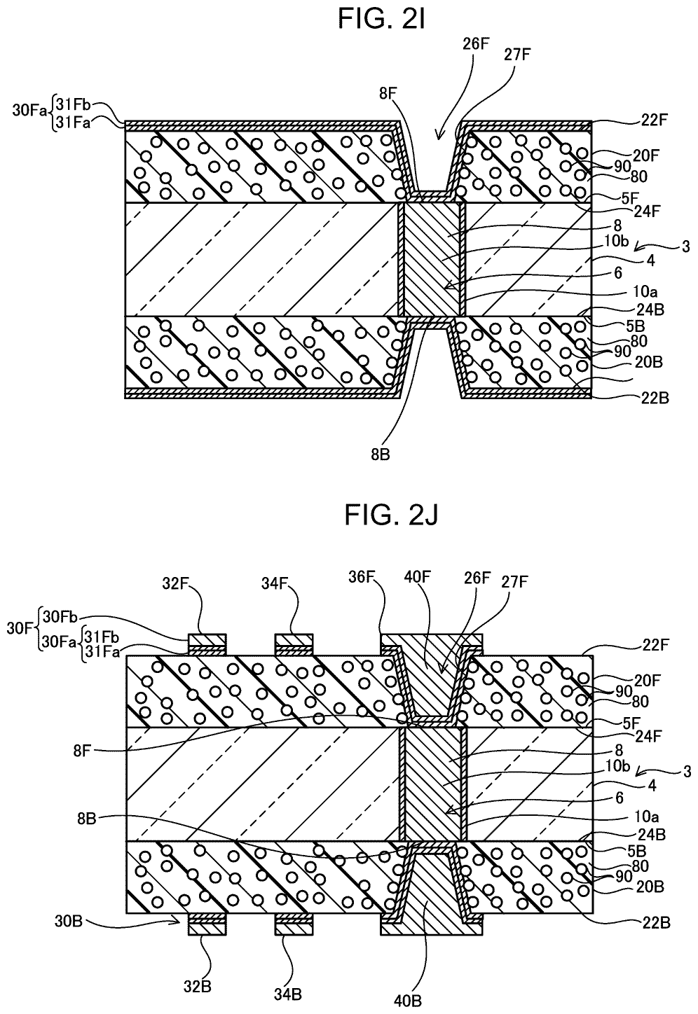

FIGS. 2A-2J illustrate a method for manufacturing the wiring substrate 2 of the embodiment. FIGS. 2A-2J are cross-sectional views. FIG. 2A illustrates the glass substrate 4. The substrate 4 has the front surface (5F) and the back surface (5B). As illustrated in FIG. 2B, the through holes 6 each extending from the front surface (5F) to the back surface (5B) are formed. The through holes 6 penetrate the substrate 4. Laser is irradiated from the front surface (5F) side of the substrate 4. After that, the substrate 4 is immersed in a hydrofluoric acid. The through holes 6 are formed.

As illustrated in FIG. 2C, the seed layer (10a) is formed. The seed layer (10a) is formed by electroless plating. The seed layer (10a) is formed on the inner wall surfaces of the through holes 6, on the front surface (5F), and on the back surface (5B).

As illustrated in FIG. 2D, the electrolytic plating layer (10b) is formed. The electrolytic plating layer (10b) is formed on the seed layer (10a). The electrolytic plating layer (10b) fills the through holes 6.

As illustrated in FIG. 2E, the electrolytic plating layer (10b) and the seed layer (10a) on the front surface (5F) are removed by polishing. The electrolytic plating layer (10b) and the seed layer (10a) on the back surface (5B) are removed by polishing. The front surface (5F) and the back surface (5B) of the substrate 4 are exposed. The through-hole conductors 8 are formed by the seed layer (10a) on the inner wall surfaces of the through holes 6 and the electrolytic plating layer (10b) on the seed layer (10a). The upper ends (8F) of the through-hole conductors 8 are exposed from the front surface (5F). The lower ends (8B) of the through-hole conductors 8 are exposed from the back surface (5B). Surfaces forming the upper ends (8F) and the front surface (5F) form the same flat surface. Surfaces forming the lower ends (8B) and the back surface (5B) form the same flat surface. The core substrate 3 (FIG. 1) is formed. The core substrate 3 in FIG. 1 has no conductor circuit on the front surface (5F). The core substrate 3 in FIG. 1 has no conductor circuit on the back surface (5B).

The front side build-up layer (300F) and the back side build-up layer (300B) are formed on core substrate 3 using similar methods. The method for forming the front side build-up layer (300F) is described below. The back side build-up layer (300B) is also depicted in the drawings.

As illustrated in FIG. 2F, the first resin insulating layer (20F) and a protective film (50F) are formed on the front surface (5F) of the substrate 4 and on the upper ends (8F). The second surface (24F) of the first resin insulating layer (20F) faces the front surface (5F) of the substrate 4. The protective film (50F) is formed on the first surface (22F) of the first resin insulating layer (20F). The first surface (22F) of the first resin insulating layer (20F) is formed only of the resin 80. No inorganic particles 90 are exposed from the first surface (22F). The first surface (22F) does not include surfaces of the inorganic particles 90. No unevenness is formed on the first surface (22F) of the first resin insulating layer (20F). The first resin insulating layer (20F) is formed on a flat surface formed by the front surface (5F) and the upper ends (8F). Therefore, the first surface (22F) is formed as a substantially flat surface. The front surface (5F) and the first surface (22F) are substantially parallel.

As illustrated in FIG. 2G, laser (L) is irradiated from above the protective film (50F). The laser (L) penetrates the protective film (50F) and the first resin insulating layer (20F) at the same time. The first openings (26F) for via conductors reaching the upper ends (8F) of the through-hole conductors 8 are formed. The laser (L) is, for example, UV laser, or CO₂ laser. The upper ends (8F) of the through-hole conductors 8 are exposed from the first openings (26F). When the first openings (26F) are formed, the first surface (22F) is covered by the protective film (50F). When the first openings (26F) are formed, even when the resin scatters, adherence of the resin to the first surface (22F) is suppressed.

The first surface (22F) is excellent in flatness. When the laser (L) is irradiated to the first surface (22F), the laser (L) is unlikely to be diffusely reflected. When each of the first openings (26F) is formed, a focus position of the laser (L) is likely to match. Openings for via conductors with small diameters can be formed. The diameters of the openings for via conductors are substantially equal to each other. For example, openings for via conductors having diameters of 15 μm or more and 35 μm or less can be formed. The diameters are measured on the first surface (22F).

Insides of the first openings (26F) are cleaned. By cleaning the insides of the first openings (26F), resin residues generated when the first openings (26F) are formed are removed. The cleaning of the insides of the first openings (26F) is performed using plasma. That is, the cleaning is performed with a dry process. The cleaning includes a desmear treatment. By the plasma, the resin 80 is selectively removed. The plasma removes the resin 80 faster than the inorganic particles 90. The inner wall surfaces (27F) of the first openings (26F) are roughened by the plasma.

By cleaning the insides of the first openings (26F), the inorganic particles 90 are exposed on the inner wall surfaces (27F) of the first openings (26F) (FIG. 2G). The inner wall surface (27F) of each of the first openings (26F) includes surfaces of the inorganic particles 90. The inner wall surface (27F) of each of the first openings (26F) has unevenness. On the other hand, the first surface (22F) of the first resin insulating layer (20F) is covered by the protective film (50F). The first surface (22F) is not affected by the plasma. The first surface (22F) is formed only of the resin 80. No inorganic particles 90 are exposed from the first surface (22F). The first surface (22F) does not include surfaces of the inorganic particles 90. The first surface (22F) of the first resin insulating layer (20F) has no unevenness. The first surface (22F) is formed smooth.

As illustrated in FIG. 2H, the protective film (50F) is removed from the resin insulating layer (20F). After the protective film (50F) is removed, the first surface (22F) of the first resin insulating layer (20F) is not roughened.

As illustrated in FIG. 2I, the seed layer (30Fa) is formed on the first surface (22F) of the first resin insulating layer (20F). The seed layer (30Fa) is formed by sputtering. The formation of the seed layer (30Fa) is performed with a dry process. The seed layer (30Fa) is also formed on the upper ends (8F) of the through-hole conductors 8 exposed from the first openings (26F) and on the inner wall surfaces (27F) of the first openings (26F). The seed layer (30Fa) is mainly formed of copper. The first layer (31Fa) is formed on the first surface (22F) by sputtering. The first layer (31Fa) is formed by sputtering on the inner wall surfaces (27F) exposed from the first openings (26F) and on the upper ends (8F) of the through-hole conductors 8. The second layer (31Fb) is formed on the first layer (31Fa) by sputtering.

The first surface (22F) is excellent in flatness. When the seed layer (30Fa) is formed on the first surface (22F) by sputtering, a distance between a target and the first surface (22F) is substantially constant. A seed layer (30Fa) having a substantially uniform thickness can be formed.

A plating resist is formed on the seed layer (30Fa). The plating resist has openings for forming the first signal wiring (32F), the second signal wiring (34F), and the lands (36F) (FIG. 1).

The electrolytic plating layer (30Fb) is formed on the seed layer (30Fa) exposed from the plating resist. The electrolytic plating layer (30Fb) fills the first openings (26F). The first signal wiring (32F), the second signal wiring (34F), and the lands (36F) (FIG. 1) are formed by the seed layer (30Fa) and the electrolytic plating film (30Fb) on the first surface (22F). The first conductor layer (30F) is formed. The first via conductors (40F) (FIG. 1) are formed by the seed layer (30Fa) and the electrolytic plating film (30Fb) in the first openings (26F). The first via conductors (40F) connect the through-hole conductors 8 and the lands (36F). The first signal wiring (32F) and the second signal wiring (34F) form a pair wiring.

The plating resist is removed. The seed layer (30Fa) exposed from the electrolytic plating layer (30Fb) is removed. As illustrated in FIG. 2J, the first conductor layer (30F) and the first via conductors (40F) are formed at the same time.

The second resin insulating layer (120F) is formed on the first surface (22F) of the first resin insulating layer (20F) and on the first conductor layer (30F). The second conductor layer (130F) is formed on the first surface (122F) of the second resin insulating layer (120F). The second via conductors (140F) are formed in the second openings (126F) of the second resin insulating layer (120F). The second resin insulating layer (120F) is formed using the same method as the first resin insulating layer (20F). The second conductor layer (130F) is formed using the same method as the first conductor layer (30F). The second via conductors (140F) are formed using the same method as the first via conductors (40F). The wiring substrate 2 of the embodiment (FIG. 1) is obtained.

The core substrate 3 of the wiring substrate 2 of the embodiment (FIG. 1) includes the glass substrate 4. The glass substrate 4 is excellent in flatness. The first surface (22F, 22B) of the first resin insulating layer (20F, 20B) is formed of the resin 80. The first surface (22F, 22B) of the first resin insulating layer (20F, 20B) is formed only of the resin 80. The first surface (22F, 22B) of the first resin insulating layer (20F, 20B) does not include surfaces of the inorganic particles 90. The first surface (22F, 22B) of the first resin insulating layer (20F, 20B) is excellent in flatness and smoothness. Fine signal wirings (32F, 32B, 34F, 34B) can be formed on the first surface (22F, 22B) of the first resin insulating layer (20F, 20B). The first surface (122F, 122B) of the second resin insulating layer (120F, 120B) is similar to the first surface (22F, 22B) of the first resin insulating layer (20F, 20B). Therefore, fine signal wirings (132F, 132B, 134F, 134B) can be formed on the first surface (122F, 122B) of the second resin insulating layer (120F, 120B). The L/S of a signal wiring formed according to the embodiment is, for example, less than (5 μm)/(5 μm). The L/S of a signal wiring is preferably (1.5 μm)/(1.5 μm) or more and (3.5 μm)/(3.5 μm) or less. L means a width of a signal wiring, and S means a width of a space between adjacent signal wirings.

The inner wall surface of each of the openings (the first openings and the second openings) for the via conductors is formed of the resin 80 and surfaces of the inorganic particles 90. The first layer formed on the inner wall surface is formed by sputtering. It is thought that, when the first layer is formed, particles forming the sputtered film adhere to the inorganic particles 90 on the inner wall surface. It is thought that the particles that form the sputtered film are not embedded in the inorganic particles 90. A thin and continuous seed layer can be formed on the inner wall surface. According to the embodiment, a thin and continuous seed layer can be formed on the first surface and the inner wall surface. Fine signal wirings can be formed.

In the wiring substrate 2 (FIG. 1) of the embodiment, the first surface (22F, 22B) of the first resin insulating layer (20F, 20B) is formed of the resin 80. No inorganic particles 90 are exposed from the first surface (22F, 22B). No unevenness is formed on the first surface (22F, 22B). An increase in standard deviation of a relative permittivity in a portion near the first surface (22F, 22B) of the first resin insulating layer (20F, 20B) is suppressed. The relative permittivity of the first surface (22F, 22B) does not significantly vary depending on a location. Even when the first signal wiring (32F, 32B) and the second signal wiring (34F, 34B) are in contact with the first surface (22F, 22B), a difference in propagation speed of an electrical signal between the first signal wiring (32F, 32B) and the second signal wiring (34F, 34B) can be reduced. Therefore, in the wiring substrate 2 of the embodiment, noise is suppressed. Even when a logic IC is mounted on the wiring substrate 2 of the embodiment, data transmitted via the first signal wiring (32F, 32B) and data transmitted via the second signal wiring (34F, 34B) arrive at the logic IC substantially without delay. Malfunction of the logic IC can be suppressed. Even when a length of the first signal wiring (32F, 32B) and a length of the second signal wiring (34F, 34B) are 5 mm or more, a difference in the propagation speed between the two can be reduced. Even when the length of the first signal wiring (32F, 32B) and the length of the second signal wiring (34F, 34B) are 10 mm or more and 20 mm or less, malfunction of the logic IC can be suppressed. The first surface (122F, 122B) of the second resin insulating layer (120F, 120B) is similar to the first surface (22F, 22B) of the first resin insulating layer (20F, 20B). Therefore, the first signal wiring (132F, 132B) and the second signal wiring (134F, 134B) have similar effects as the first signal wiring (32F, 32B) and the second signal wiring (34F, 34B). A high quality wiring substrate 2 is provided.

### Modified Examples

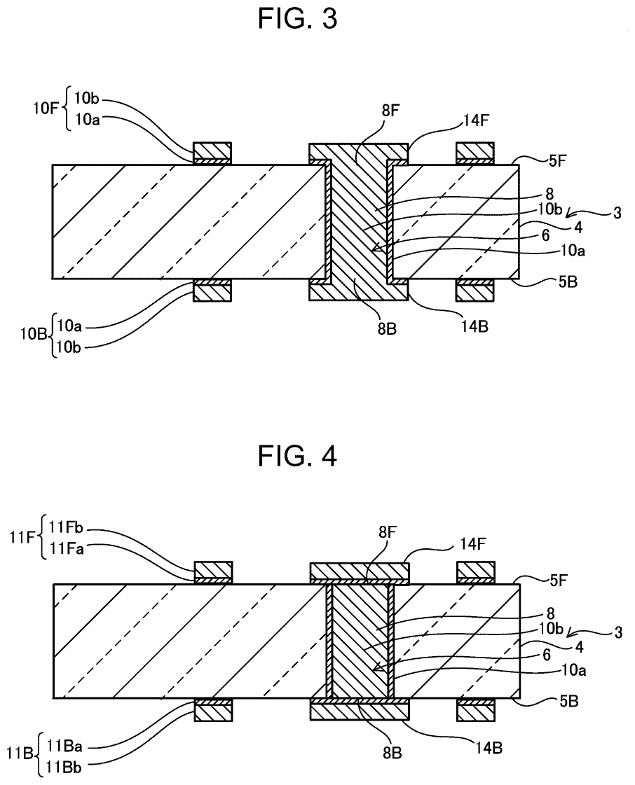

Similar to the embodiment, wiring substrates of modified examples each include a core substrate 3, a front side build-up layer (300F), and a back side build-up layer (300B). The core substrate 3 of the embodiment is different from the core substrates 3 of the modified examples. The front side build-up layer (300F) of the embodiment is the same as the front side build-up layer (300F) of each of the modified examples. The back side build-up layer (300B) of the embodiment is the same as the back side build-up layer (300B) of each of the modified examples. Cross-sections of the core substrates 3 of the modified examples are respectively illustrated in FIGS. 3 and 4. As illustrated in FIGS. 3 and 4, the core substrates 3 of the modified examples respectively have conductor layers (10F, 11F) on the front surface (5F) of the glass substrate 4. The conductor layers (10F, 11F) each include lands (14F) covering the upper ends (8F) of the through-hole conductors 8. Further, the core substrates 3 of the modified examples respectively have conductor layers (10B, 11B) on the back surface (5B) of the substrate 4. The conductor layers (10B, 11B) each include lands (14B) covering the lower ends (8B) of the through-hole conductors 8. The lands (14F) and the lands (14B) are electrically connected by the through-hole conductors 8. The core substrate 3 of the embodiment has no conductor layer on the front surface (5F) and no conductor layer on the back surface (5B).

In the modified examples, the front side resin insulating layer (resin insulating layer directly above the core substrate) forming the front side build-up layer (300F) is formed on the conductor layer (10F, 11F) and the front surface (5F). The resin insulating layer (first resin insulating layer (20F)) directly above the core substrate has openings (first openings (26F)) for via conductors reaching the lands (14F). Via conductors (first via conductors (40F)) similar to those of the embodiment are formed in the openings for via conductors. Since the via conductors penetrating the resin insulating layer directly above the core substrate reach the lands (14F), the seed layer (first layer (31Fa)) forming the via conductors is in contact with upper surfaces of the lands (14F) and inner wall surfaces of the openings. The via conductors penetrating the resin insulating layer directly above the core substrate are electrically connected to the through-hole conductors 8 via the lands (14F).

In the modified examples, the back side resin insulating layer (resin insulating layer directly below the core substrate) forming the back side build-up layer (300B) is formed on the conductor layer (10B, 11B) and the back surface (5B). The resin insulating layer (first resin insulating layer (20B)) directly below the core substrate has openings (first openings) for via conductors reaching the lands (14B). Via conductors (first via conductors (40B)) similar to those of the embodiment are formed in the openings for via conductors. Since the via conductors penetrating the resin insulating layer directly below the core substrate reach the lands (14B), the seed layer forming the via conductors is in contact with upper surfaces of the lands (14B) and inner wall surfaces of the openings. The via conductors penetrating the resin insulating layer directly below the core substrate are electrically connected to the through-hole conductors 8 via the lands (14B).

### Method for Manufacturing Wiring Substrate

The core substrate 3 illustrated in FIG. 3 is a core substrate 3 of a first example. A method for manufacturing the core substrate 3 of the first example is described below. An intermediate substrate illustrated in FIG. 2D is prepared. The conductor layer (10F) is formed on the front surface (5F) using a subtractive method. The conductor layer (10B) is formed on the back surface (5B). The core substrate 3 of the first example of the modified examples is obtained.

The conductor layer (10F) is formed of the seed layer (10a) and the electrolytic plating layer (10b) on the seed layer (10a). The conductor layer (10B) is formed of the seed layer (10a) and the electrolytic plating layer (10b) on the seed layer (10a). The seed layer (10a) is formed by electroless plating. The seed layer (10a) forming the conductor layer (10F), the seed layer (10a) forming the conductor layer (10B), and the seed layer (10a) forming the through-hole conductors 8 are common. The electrolytic plating layer (10b) forming the conductor layer (10F), the electrolytic plating layer (10b) forming the conductor layer (10B), and the electrolytic plating layer (10b) forming the through-hole conductors 8 are common. The conductor layers (10F, 10B) and the through-hole conductors 8 are formed at the same time. The through-hole conductors 8 and the lands (14F, 14B) are formed at the same time. The through-hole conductors 8 and the lands (14F, 14B) are integrally formed. There is no seed layer between the upper ends (8F) and the lands (14F). There is no seed layer between the lower ends (8B) and the lands (14B).

The core substrate 3 illustrated in FIG. 4 is the core substrate 3 of a second example. A method for manufacturing the core substrate 3 of the second example is described below. An intermediate substrate illustrated in FIG. 2E is prepared. Seed layers (11Fa, 11Ba) are respectively formed on the front surface (5F) and the back surface (5B). The seed layers (11Fa, 11Ba) are formed by electroless plating. It is also possible that the seed layers (11Fa, 11Ba) are formed by sputtering. The seed layer (11Fa) covers the front surface (5F) of the substrate 4 and the upper ends (8F) of the through-hole conductors 8. The seed layer (11Ba) covers the back surface (5B) of the substrate 4 and the lower ends (8B) of the through-hole conductors 8. Electrolytic plating layers (11Fb, 11Bb) are respectively formed on the seed layers (11Fa, 11Ba). After that, the conductor layers (11F, 11B) are formed using a subtractive method. The core substrate 3 of the second example of the modified examples is obtained.

The conductor layer (11F) is formed of the seed layer (11Fa) and the electrolytic plating layer (11Fb) on the seed layer (11Fa). The conductor layer (11B) is formed of the seed layer (11Ba) and the electrolytic plating layer (11Bb) on the seed layer (11Ba). The seed layer (11Fa) is formed on the front surface (5F) of the substrate 4. The seed layer (11Fa) covers the upper ends (8F) of the through-hole conductors 8. The seed layer (11Ba) is formed on the back surface (5B) of the substrate 4. The seed layer (11Ba) covers the lower ends (8B) of the through-hole conductors 8. The seed layers (11Fa, 11Ba) are formed by electroless plating. It is also possible that the seed layers (11Fa, 11Ba) are formed by sputtering. The seed layers (11Fa, 11Ba) that respectively form the conductor layers (11F, 11B) and the seed layer (10a) that forms the through-hole conductors 8 are different from each other. The electrolytic plating layers (11Fb, 11Bb) that respectively form the conductor layers (11F, 11B) and the electrolytic plating layer (10b) that forms the through-hole conductors 8 are different from each other. The conductor layers (11F, 11B) and the through-hole conductors 8 are separately formed. In the second example, the seed layer (11Fa) forming the lands (14F) exists between the electrolytic plating layer (10b) forming the upper ends (8F) and the electrolytic plating layer (11Fb) forming the lands (14F). The seed layer (11Ba) forming the lands (14B) exists between the electrolytic plating layer (10b) forming the lower ends (8B) and the electrolytic plating layer (11Bb) forming the lands (14B). In contrast, in the first example (FIG. 3), the electrolytic plating layer (10b) forming the upper ends (8F) and the electrolytic plating layer (10b) forming the lands (14F) are continuous. The electrolytic plating layer (10b) forming the lower ends (8B) and the electrolytic plating layer (10b) forming the lands (14B) are continuous.

The front side build-up layer (300F) and back side build-up layer (300B) are formed on the core substrate 3 of each of the modified examples in the same way as the embodiment.

In Japanese Patent Application Laid-Open Publication No. 2015-133473, light transmittance of a first insulating layer formed of a glass material is controlled. As an example of a method for controlling the light transmittance, Japanese Patent Application Laid-Open Publication No. 2015-133473 describes that a coloring agent is contained in the first insulating layer. It is thought difficult for the first insulating layer formed of a glass material to uniformly contain a coloring agent.

A wiring substrate according to an embodiment of the present invention includes: a core substrate that has a substrate formed of glass, a through hole penetrating the substrate, and a through-hole conductor formed in the through hole; a resin insulating layer that is formed on the core substrate, and has a first surface, a second surface on the opposite side with respect to the first surface, and an opening for a via conductor extending from the first surface to the second surface; a first conductor layer that is formed on the first surface of the resin insulating layer; and a via conductor that is formed in the opening and is electrically connected to the through-hole conductor. The first conductor layer and the via conductor are formed of a seed layer and an electrolytic plating layer formed on the seed layer. The seed layer is formed by sputtering. The resin insulating layer is formed of inorganic particles and a resin, the first conductor layer includes signal wirings, the first surface of the resin insulating layer is formed of the resin, and an inner wall surface of the opening is formed of the resin and surfaces of the inorganic particles.

In a wiring substrate according to an embodiment of the present invention, the core substrate includes the glass substrate. The glass substrate is excellent in flatness. Therefore, the first surface of the resin insulating layer is excellent in flatness. The first surface is excellent in smoothness. The first surface of the resin insulating layer on the core substrate is formed of the resin. Fine signal wirings can be formed on the first surface of the resin insulating layer. The inner wall surface of the opening is formed of the resin and surfaces of the inorganic particles. The seed layer formed on the inner wall surface is formed by sputtering. The sputtered seed layer can be referred to as a sputtered film. It is thought that, when the seed layer is formed, particles forming the sputtered film adhere to the inorganic particles on the inner wall surface. It is thought that the particles that form the sputtered film are not embedded in the inorganic particles. A thin seed layer can be continuously formed on the inner wall surface. Fine signal wirings can be formed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a glass substrate;
a resin insulating layer formed on the core substrate and comprising inorganic particles and resin;
a conductor layer formed on a surface of the resin insulating layer and comprising a seed layer formed by sputtering and an electrolytic plating layer formed on the seed layer such that the conductor layer includes a plurality of signal wirings; and
a via conductor formed in the resin insulating layer such that the via conductor is formed in an opening formed in the resin insulating layer and includes the seed layer and electrolytic plating layer extending from the conductor layer,
wherein the core substrate includes a through-hole conductor formed such that the core substrate has a through hole penetrating through the glass substrate and that the through-hole conductor is formed in the through hole, the via conductor is formed such that the via conductor is electrically connected to the through-hole conductor formed in the core substrate, and the resin insulating layer is formed such that the surface upon which the conductor layer is formed includes the resin and that an inner wall surface in the opening includes the resin and the inorganic particles.

2. The wiring substrate according to claim 1, wherein the conductor layer is formed such that the plurality of signal wirings includes a pair wiring comprising a first signal wiring and a second signal wiring.

3. The wiring substrate according to claim 1, wherein the resin insulating layer is formed such that the surface upon which the conductor layer is formed does not include the inorganic particles.

4. The wiring substrate according to claim 3, wherein the resin insulating layer is formed such that the surface upon which the conductor layer is formed is formed only of the resin.

5. The wiring substrate according to claim 3, wherein the resin insulating layer is formed such that the inorganic particles are not exposed from the surface upon which the conductor layer is formed.

6. The wiring substrate according to claim 1, wherein the resin insulating layer is formed such that a content of the inorganic particles in the resin insulating layer is 75 wt % or more.

7. The wiring substrate according to claim 1, wherein the core substrate includes a conductor layer formed on the glass substrate such that the conductor layer of the core substrate includes a land covering the through-hole conductor.

8. The wiring substrate according to claim 7, wherein the core substrate is formed such that the land and the through-hole conductor are formed in a same process.

9. The wiring substrate according to claim 7, wherein the core substrate is formed such that the land and the through-hole conductor are formed in separate processes.

10. The wiring substrate according to claim 1, wherein the core substrate is formed such that no conductor circuit is formed on a surface of the glass substrate upon which the resin insulating layer is formed in contact with the surface of the glass substrate.

11. The wiring substrate according to claim 2, wherein the resin insulating layer is formed such that the surface upon which the conductor layer is formed does not include the inorganic particles.

12. The wiring substrate according to claim 11, wherein the resin insulating layer is formed such that the surface upon which the conductor layer is formed is formed only of the resin.

13. The wiring substrate according to claim 11, wherein the resin insulating layer is formed such that the inorganic particles are not exposed from the surface upon which the conductor layer is formed.

14. The wiring substrate according to claim 2, wherein the resin insulating layer is formed such that a content of the inorganic particles in the resin insulating layer is 75 wt % or more.

15. The wiring substrate according to claim 2, wherein the core substrate includes a conductor layer formed on the glass substrate such that the conductor layer of the core substrate includes a land covering the through-hole conductor.

16. The wiring substrate according to claim 15, wherein the core substrate is formed such that the land and the through-hole conductor are formed in a same process.

17. The wiring substrate according to claim 15, wherein the core substrate is formed such that the land and the through-hole conductor are formed in separate processes.

18. The wiring substrate according to claim 2, wherein the core substrate is formed such that no conductor circuit is formed on a surface of the glass substrate upon which the resin insulating layer is formed in contact with the surface of the glass substrate.

19. The wiring substrate according to claim 3, wherein the resin insulating layer is formed such that a content of the inorganic particles in the resin insulating layer is 75 wt % or more.

20. The wiring substrate according to claim 3, wherein the core substrate includes a conductor layer formed on the glass substrate such that the conductor layer of the core substrate includes a land covering the through-hole conductor.
